(19) United States
(12) Patent Application Publication
(10) Pub. No.: US 2013/0334501 A1
(43) Pub. Date: Dec. 19, 2013

(54) Field-Effect P-N Junction

(71) Applicants: William Regan, Berkeley, CA (US); Steven Byrnes, Belmont, MA (US); Alexander K. Zettl, Kensington, CA (US); Feng Wang, El Cerrito, CA (US)

(72) Inventors: William Regan, Berkeley, CA (US); Steven Byrnes, Belmont, MA (US); Alexander K. Zettl, Kensington, CA (US); Feng Wang, El Cerrito, CA (US)

(73) Assignee: The Regents of the University of California, Oakland, CA (US)

(21) Appl. No.: 13/607,347

(22) Filed: Sep. 7, 2012

Related U.S. Application Data
(60) Provisional application No. 61/535,321, filed on Sep. 15, 2011.

(51) Int. Cl. H01L 31/0216; H01L 51/42

(52) U.S. Cl. CPC H01L 31/02168; H01L 51/428
USPC 257/40; 257/432

(57) ABSTRACT

Embodiments described herein provide a field-effect p-n junction. In some embodiments, the field-effect p-n junction includes (1) an ohmic contact, (2) a semiconductor layer above the ohmic contact, (3) at least one rectifying contact above the semiconductor layer, where the lateral width of the rectifying contact is less than the semiconductor depletion width of the semiconductor layer, and (4) a gate above the rectifying contact. In some embodiments, the field-effect p-n junction includes (1) an ohmic contact, (2) a semiconductor layer above the ohmic contact, (3) a thin top contact above the semiconductor layer, where the out of plane thickness of the thin top contact is less than the Debye screening length of the thin top contact, and (4) a gate above the thin top contact.

### RELATED APPLICATIONS

This application claims priority under 35 U.S.C. §119(e) to U.S. Provisional Patent Application No. 61/535,321, filed Sep. 15, 2011, which is herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### FIELD

Embodiments described herein relate to the field of semiconductors, and particularly relate to a field-effect p-n junction.

### BACKGROUND

Photo voltaics are a promising source of renewable energy, but current technologies face a cost to efficiency tradeoff that has slowed widespread implementation. While a wide variety of photovoltaic technologies exist, the number of fundamental architectures for separating charge remains somewhat limited.

### BRIEF DESCRIPTION OF THE DRAWINGS

FIG. 1 shows an example of a cross-sectional schematic diagram of a field-effect p-n junction.

FIG. 2 shows an example of a cross-sectional schematic diagram of a field-effect p-n junction.

FIG. 3 shows an example of a cross-sectional schematic diagram of a field-effect p-n junction with a gate field applied.

FIG. 4 shows an example of a cross-sectional schematic diagram of a field-effect p-n junction.

FIG. 5 shows an example of a cross-sectional schematic diagram of a field-effect p-n junction.

### DETAILED DESCRIPTION

A dominant cell architecture, physically-doped crystalline silicon, boasts a relatively high efficiency. Devices primarily use p-n homojunctions (crystalline silicon, III-V), p-i-n homojunctions (amorphous silicon), and heterojunctions (CdTe, CIGS, polymers, Schottky barriers). However, the doping process is somewhat energy-intensive and can damage the crystal, reducing cell output.

Field-effect doping is a promising alternative strategy to chemical doping, an expensive process and one which is not possible in many materials, but most examples to date suffer from device instability or fundamental efficiency limitations ultimately due to screening of the gate by the top contact. The field effect, wherein a metal gate creates Fermi-level shifts in a nearby semiconductor, is far less commonly discussed in this context, but it can in fact produce a significant photovoltaic effect.^{1,2} Since holding a gate at a constant voltage can require little current and hence negligible power, this approach is practical for power-generation applications. However, prior art examples of field-effect doping suffer from device instability or fundamental efficiency limitations due to reliance on large metal-semiconductor Schottky barriers.

In addition to considerable energy (and cost) savings in device fabrication, a primary advantage of the field-effect architecture is that it does not require doping. This is a crucial consideration, since many of the most promising low cost and abundant semiconductors for solar cells cannot be doped to the opposite polarity, including earth-abundant metal oxides and sulfides³. Other semiconductors (such as amorphous silicon) can be doped but only at the expense of degraded properties.

Another advantage of the field-effect architecture is that, with the built-in field provided by the gate rather than by material interfaces, there is more flexibility in choosing materials to optimize other parameters such as stability, light propagation, interface quality, and processing costs. For example, the CdS—CdTe junction is crucial for generating the field in CdTe solar cells. Therefore CdS, even though it absorbs and wastes some of the incoming light, cannot be replaced with a more transparent material.

There has been sporadic work using the field effect in solar cells. Metal-insulator-semiconductor (MIS) solar cells typically use uncompensated fixed charges in a dielectric to increase the semiconductor band bending at the MIS interface, functioning in a similar way to a gate⁴. Unfortunately, these have short operating lifetimes due to the thin and unstable tunnel oxide⁵. Hybrid MIS-inversion layer (MIS-IL) cells have made use of a true gate to invert the regions between MIS contacts^{6,7}. Successful implementation of gating has also been demonstrated with amorphous Si field-effect cells, which use a gate to bend a region of intrinsic amorphous Si into n-type or p-type^{1,2}. These designs, however, have all used wide top contacts that would locally screen the gate. Since the semiconductor areas below the contacts are screened from the field effect, these devices instead rely on other strategies in addition to the gate, such as doping at the contacts^{1,2}, a significant Schottky barrier at the contacts⁴⁻⁷.

A recent study^{8,9} using carbon-nanotube contacts and an electrolyte gate has taken advantage of certain field-effect strategies without clarifying the general principles at work. By allowing the gate field to invert regions between the contacts and also partially penetrate the contacts, these cells can achieve impressively high efficiencies.

Embodiments described herein provide a field-effect p-n junction. In some embodiments, the field-effect p-n junction includes (1) an ohmic contact, (2) a semiconductor layer above or disposed on the ohmic contact, (3) at least one rectifying contact above or disposed on the semiconductor layer, where the lateral width of the rectifying contact is less than the semiconductor depletion width of the semiconductor layer, and (4) a gate above or disposed on the rectifying contact. In some embodiments the field-effect p-n junction includes (1) an ohmic contact, (2) a semiconductor layer above or disposed on the ohmic contact, (3) a thin top contact above or disposed on the semiconductor layer, where the out of plane thickness of the thin top contact is less than the Debye screening length of the thin top contact, and (4) a gate above or disposed on the thin top contact.

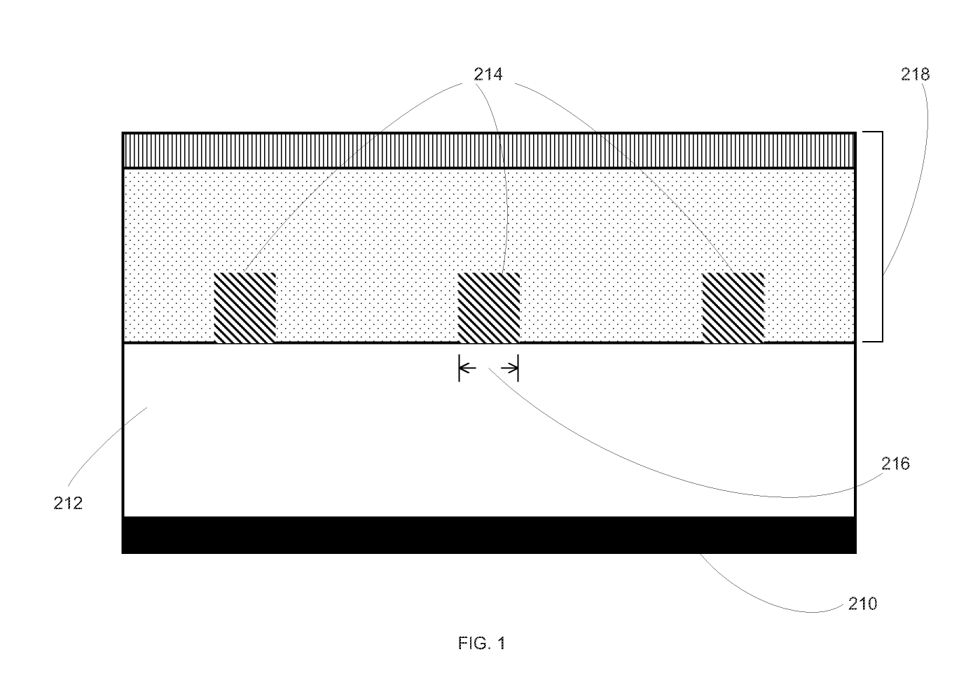

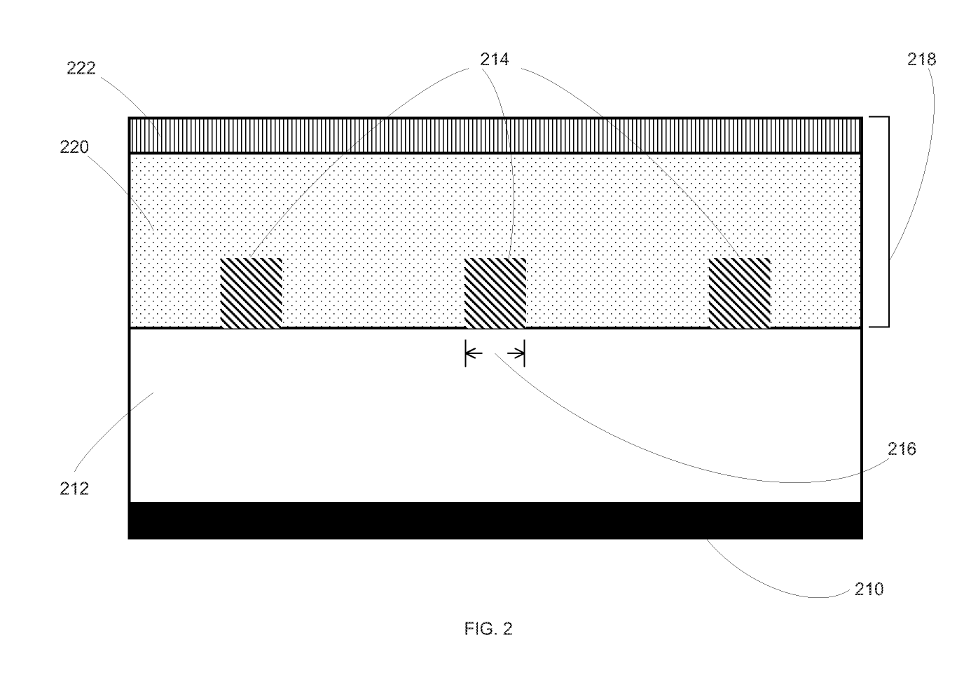

Referring to FIG. 1, some embodiments include an ohmic contact 210, a semiconductor layer 212 above or disposed on ohmic contact 210, at least one rectifying contact 214 above or disposed on semiconductor layer 212, where the lateral width 216 of rectifying contact 214 is less than the semiconductor depletion width of semiconductor layer 212, and a gate 218 above or disposed on rectifying contact 214. Referring to FIG. 2, in some embodiments, gate 218 includes a dielectric 220 above or disposed on rectifying contact 214 and semiconductor layer 220 and an electrode 222 above or disposed on dielectric 220.

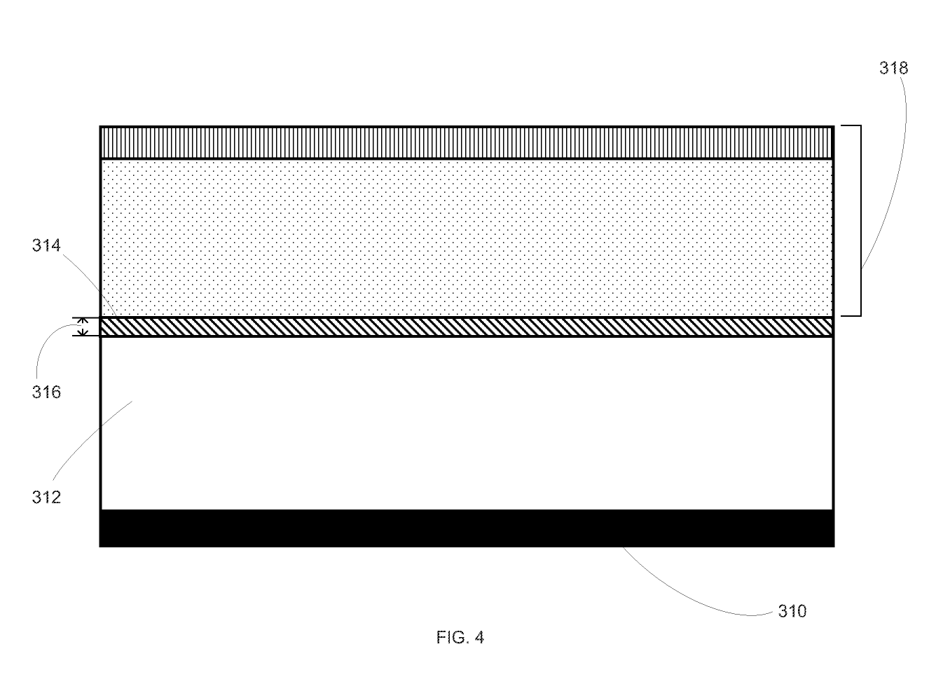

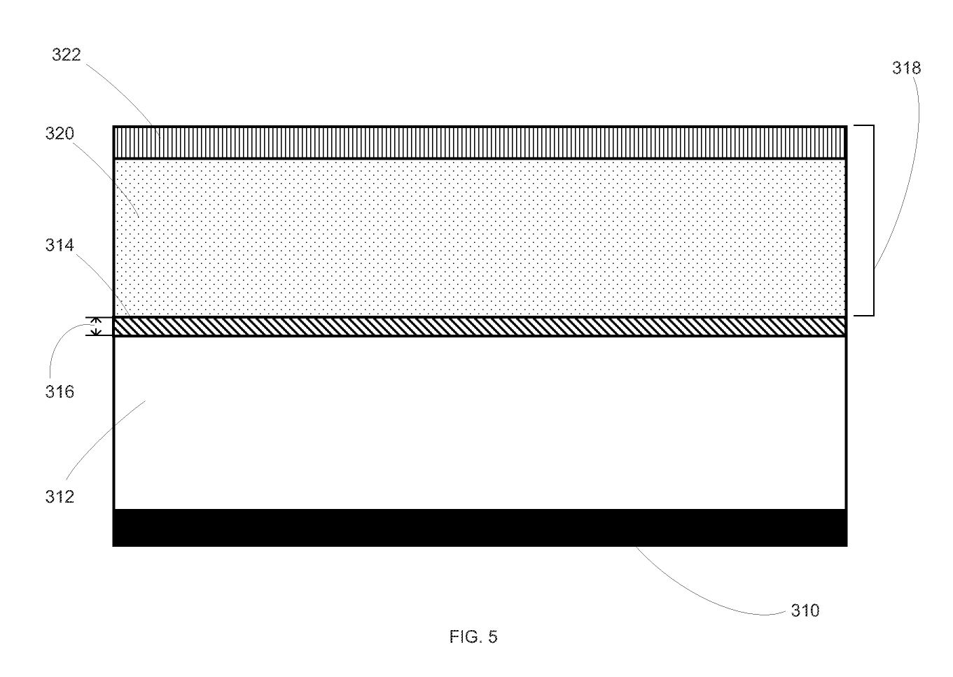

Referring to FIG. 4, some embodiments include an ohmic contact 310, a semiconductor layer 312 above or disposed on ohmic contact 310, a thin top contact 314 above or disposed on semiconductor layer 312, where the out of plane thickness 316 of thin top contact 314 is less than the Debye screening length of thin top contact 314, and a gate 318 above or disposed on thin top contact 314. Referring to FIG. 5, in some embodiments, gate 318 includes a dielectric 320 above or disposed on thin top contact 314 and an electrode 322 above or disposed on dielectric 320.

### Semiconductor Layer

In some embodiments, semiconductor layer 212 and semiconductor layer 312 include an inorganic semiconductor. In a particular embodiment, the inorganic semiconductor is selected from the group consisting of Si, Ge, CdTe, CdS, GaAs, InxGayN, CuxO, CuxS, copper-indium-gallium-selenium (CIGS), FeS2, FexOy, InP, copper-zinc-tin-sulfur (CZTS), and PbS.

In some embodiments, semiconductor layer 212 and semiconductor layer 312 include an organic semiconductor. In a particular embodiment, the organic semiconductor is selected from the group consisting of pentacene, poly(3-hexyithiophene) (P3HT), and [6,6]-phenyl-C61-butyric acid methyl ester (PCBM).

### Rectifying Contact

In some embodiments, rectifying contact 214 includes a metal. In a particular embodiment, the metal is selected from the group consisting of Cr, Cu, Ni, Fe, In, Au, Al, Ag, C, and Ti.

In some embodiments, rectifying contact 214 includes a semi-metal. In a particular embodiment, the semi-metal is selected from the group consisting of Bi and Sn. In a particular embodiment, the semi-metal is selected from the group consisting of monolayer graphene and few-layer graphene.

### Electrolyte

In some embodiments, rectifying contact 214 includes a semiconductor. In some embodiments, the semiconductor includes an inorganic semiconductor. In a particular embodiment, the inorganic semiconductor is selected from the group consisting of Si, Ge, CdTe, CdS, GaAs, InxGayN, CuxO, CuxS, copper-indium-gallium-selenium (CIGS), FeS2, FexOy, InP, copper-zinc-tin-sulfur (CZTS), and PbS. In some embodiments, the semiconductor includes an organic semiconductor. In a particular embodiment, the organic semiconductor is selected from the group consisting of pentacene, poly(3-hexylthiophene) (P3HT), and [6,6]-phenyl-C61-butyric acid methyl ester (PCBM).

### Gate

Dielectric

In some embodiments, dielectric 220 and dielectric 320 include inorganic material. In a particular embodiment, the inorganic material is selected from the group consisting of SiO2, Si3N4, and high-k dielectrics.

In some embodiments, dielectric 220 and dielectric 320 include organic material. In some embodiments, the organic material includes a polymer. In a particular embodiment, the polymer is selected from the group consisting of poly(methyl methacrylate (PMMA), polyethyleneimine (PEI), and polystyrene (PS).

Electrode

In some embodiments, electrode 222 and electrode 322 include a semitransparent metal. In some embodiments, the semitransparent metal includes a thin metal film. In a particular embodiment, the thin metal film is selected from the group consisting of Cr, Cu, Ni, Fe, In, Au, Al, Ag, C, and Ti.

In some embodiments, electrode 222 and electrode 322 include a transparent conducting oxide (TCO). In a particular embodiment, the TCO is selected from the group consisting of tin-doped indium-oxide (ITO), zinc tin oxide (ZTO), and aluminum-doped zinc oxide (AZO).

In some embodiments, electrode 222 and electrode 322 include a semi-metal. In a particular embodiment, the semi-metal is selected from the group consisting of mono-layer graphene and few-layer graphene.

Electrolyte

In some embodiments, gate 218 and gate 318 include an electrolyte. In some embodiments, the electrolyte includes an ionic liquid. In a particular embodiment, the ionic liquid includes 1-ethyl-3-methylimidazolium bis(trifluoroniethylsulphonyl)imide ([EMIM][TFSI]).

In some embodiments, gate 218 and gate 318 include an ionic gel. In some embodiments, the ionic gel includes an ionic liquid mixed with at least one thickening agent. In a particular embodiment, the thickening agent is selected from the group consisting of diblock copolymers and triblock copolymers.

Anti-Reflection Coating

In some embodiments, gate 218 and gate 318 are each configured as an anti-reflection coating, where the anti-reflection coating is configured to allow light to propagate into semiconductor layer 212 and semiconductor layer 312. In some embodiments, the anti-reflection coating is configured to allow a maximum amount of light to propagate into semiconductor layer 212 and semiconductor layer 312.

Tuning Electrical Properties

In some embodiments, gate 318 is configured to tune the electrical properties of thin contact 314 so as to alter the interface between thin contact 314 and semiconductor layer 312.

### Thin Top Contact

In some embodiments, thin top contact 314 includes a semi-metal. In a particular embodiment, the semi-metal is selected from the group consisting of mono-layer graphene and few-layer graphene.

In some embodiments, thin top contact 314 includes a metal. In a particular embodiment, the metal is selected from the group consisting of Cr, Cu, Ni, Fe, In, Au, Al, Ag, C, and Ti.

In some embodiments, thin top contact 314 includes a semiconductor. In some embodiments, the semiconductor includes an inorganic semiconductor. In a particular embodiment, the inorganic semiconductor is selected from the group consisting of Si, Ge, CdTe, CdS, GaAs, InxGayN, CuxO, CuxS, copper-indium-gallium-selenium (CIGS), FeS2, FexOy, InP, copper-zinc-tin-sulfur (CZTS), and PbS. In some embodiments, the semiconductor includes an organic semiconductor. In a particular embodiment, the organic semiconductor is selected from the group consisting of pentacene, poly(3-hexylthiophene) (P3HT), and [6,6]-phenyl-C61-butyric acid methyl ester (PCBM).

In some embodiments, out of plane thickness 316 of thin contact 314 allows gate fields to penetrate thin top contact 314.

### General

Embodiments described herein provide a field-effect architecture, that includes a top contact geometry to control screening of the gate, that enables simple, inexpensive, and scalable fabrication of high efficiency single junction photo voltaics in nearly any singly-doped semiconductor, including several previously unusable low cost and earth-abundant semiconductors (metal oxides).

Embodiments described herein allow the field effect on its own to create the junction. Embodiments described herein provide screening-engineered field-effect photovoltaics (SFPV). By relaxing the typical constraints on contacts and materials, the embodiments described herein enable gate control of an electrically-contacted, high quality p-n junction in nearly any singly-doped semiconductor with a range of contact materials. The embodiments described herein yield robust field-effect solar cells with industry standards such as Si and CdTe and may enable fabrication of low cost, high efficiency photovoltaics from earth-abundant, direct bandgap semiconductors such as metal oxides.

Minimal screening of an applied gate field by the top contact (rectifying contact 214 and thin top contact 314), which allows for simultaneous electrical contact to and carrier modulation of the top surface of the semiconductor, is achieved by restricting one dimension of the top metal contact. This can be achieved in two distinct ways, either (i) by limiting the lateral width or (ii) the out-of-plane thickness of the metal contact, as shown schematically in FIG. 1, FIG. 2, FIG. 4, and FIG. 5. In both devices, the gate dielectric (dielectric 220 and dielectric 320) can conveniently serve a dual role as the antireflection coating (ARC).

Rectifying Contact Configuration

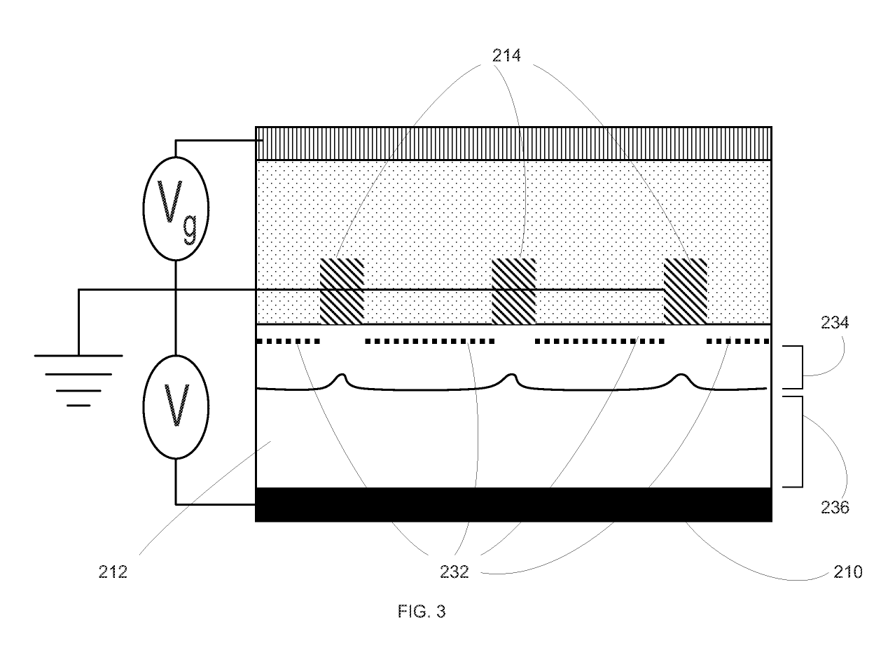

Referring to FIG. 3, a gate field is applied through a narrow top contact, rectifying contact 214. If rectifying contact 214 is sufficiently narrow relative to the semiconductor depletion width of semiconductor layer 212, a sufficient gate field can create a low resistance inversion layer 232 between rectifying contacts 214 and deplete semiconductor layer 212 beneath rectifying contacts 214, creating a p-n junction and pinching off this shunt path through semiconductor layer 212. Current flows through the fingers, rectifying contacts 214, to the adjacent inverted layer 232, through the depletion region 234, and into the unaffected, as-doped region 236 of semiconductor layer 212.

Thin Top Contact Configuration

Referring to FIG. 4 and FIG. 5, out of plane thickness 316 of the top contact, thin top contact 314, is chosen to be thinner than its Debye screening length, in order to allow electric fields to penetrate and deplete/invert the underlying semiconductor layer 312.

### REFERENCES

1. H. Koinuma et al. Mater. Res. Soc. Symp. Proc. 426, 95 (1996).
2. G. De Cesare et al. Thin Solid Films 427, 166 (2003).
3. C. Wadia et al. Environ. Sci. Technol. 43, 2072 (2009).
4. R. B. Godfrey and M. A. Green. Appl. Phys. Lett. 34, 790-793 (1979).
5. N. G. Gomaa. Renewable Energy 24, 529 (2001).
6. D.-K. Yeh and T. A. DeMassa. Solid-State Electronics 27 (3) 283 (1984).
7. V. Yu. Yerokhov and I. I. Melnyk. Solid-State Electronics 42 (6), 883 (1998).
8. P. Wadhwa et al. Nano Letters 10(12), 5001 (2010).
9. P. Wadhwa et al. Nano Letters 11(6), 4219 (2011).
10. M. A. Green. Appl. Phys. Lett. 27, 287 (1975).
11. X. Li et al. Nano Letters 9(12), 4359 (2009).
12. C. R. Crowell and S. M. Sze. Solid-State Electronics 9, 1035 (1966).
13. S. M. Sze and K. K. Ng. Physics of Semiconductor Devices 3rd ed. Wiley-Interscience: Hoboken, 2007.

14. X. Li et al. Nano Letters 10, 4328 (2010).

### CONCLUSION

It is to be understood that the above description and examples are intended to be illustrative and not restrictive. Many embodiments will be apparent to those of ordinary skill in the art upon reading the above description and examples. The scope of the embodiments should, therefore, be determined not with reference to the above description and examples, but should instead be determined with reference to the appended claims, along with the full scope of equivalents to which such claims are entitled. The disclosures of all articles and references, including patent applications and publications, are incorporated herein by reference.

What is claimed is:

1. A field-effect p-n junction comprising:
an ohmic contact;
a semiconductor layer above the ohmic contact;
at least one rectifying contact above the semiconductor layer, wherein the lateral width of the rectifying contact is less than the semiconductor depletion width of the semiconductor layer; and
a gate above the rectifying contact.

2. The p-n junction of claim 1, wherein the semiconductor layer is selected from the group consisting of an inorganic semiconductor and an organic semiconductor.

3. The p-n junction of claim 1, wherein the rectifying contact is selected from the group consisting of a metal, a semi-metal, and a semiconductor.

4. The p-n junction of claim 1, wherein the gate comprises:
a dielectric; and
an electrode above the dielectric.

5. The p-n junction of claim 4, wherein the dielectric is selected from the group consisting of an inorganic material and an organic material.

6. The p-n junction of claim 4, wherein the electrode is selected from the group consisting of a semi transparent metal, a transparent conducting oxide (TCO), and a semi-metal.

7. The p-n junction of claim 1, wherein the gate comprises an electrolyte.

8. The p-n junction of claim 1, wherein the gate is configured as an anti-reflection coating, and wherein the anti-reflection coating is configured to allow light to propagate into the semiconductor layer.

9. A field-effect p-n junction comprising:
an ohmic contact;
a semiconductor layer above the ohmic contact;
a thin top contact above the semiconductor layer, wherein the out of plane thickness of the thin top contact is less than the Debye screening length of the thin top contact; and
a gate above the thin top contact.

10. The p-n junction of claim 9, wherein the semiconductor layer is selected from the group consisting of an inorganic semiconductor and an organic semiconductor.

11. The p-n junction of claim 9, wherein the thin top contact is selected from the group consisting of a semi-metal, a metal, and a semiconductor.

12. The p-n junction of claim 9, wherein the out of plane thickness of the thin top contact is configured to allow gate fields to penetrate the thin top contact.

13. The p-n junction of claim 9, wherein the gate is configured to tune the electrical properties of the thin top contact so as to alter the interface between the thin top contact and the semiconductor layer.

14. The p-n junction of claim 9, wherein the gate comprises:
a dielectric; and
an electrode above the dielectric.

15. The p-n junction of claim 14, wherein the dielectric is selected from the group consisting of an inorganic material and an organic material.

16. The p-n junction of claim 14, wherein the electrode is selected from the group consisting of a semitransparent metal, a transparent conducting oxide (TCO), and a semi-metal.

17. The p-n junction of claim 9, wherein the gate comprises an electrolyte.

18. The p-n junction of claim 9, wherein the gate is configured as an anti-reflection coating, and wherein the anti-reflection coating is configured to allow light to propagate into the semiconductor layer.
